(19) United States
(12) Patent Application Publication
(10) Pub. No.: US 2025/0345894 A1
(43) Pub. Date: Nov. 13, 2025

(54) METHOD OF MANUFACTURING CHEMICAL MECHANICAL POLISHING SLURRY AND METHOD OF MANUFACTURING SEMICONDUCTOR DEVICE USING THE SAME

(71) Applicant: SAMSUNG ELECTRONICS CO., LTD., Suwon-si (KR)

(72) Inventors: Imbi YEO, Suwon-si (KR); Seyun Park, Suwon-si (KR)

(73) Assignee: SAMSUNG ELECTRONICS CO., LTD., Suwon-si (KR)

(21) Appl. No.: 18/974,007

(22) Filed: Dec. 9, 2024

(30) Foreign Application Priority Data
May 13, 2024 (KR) 10-2024-0062753

(51) Int. Cl. B24B 37/24; H01L 21/67

(52) U.S. Cl. CPC B24B 37/24; H01L 21/67092

(57) ABSTRACT

A chemical mechanical polishing apparatus includes: a polishing pad on a platen; an arm extending from an edge of the polishing pad to a center of the polishing pad or at least near the center of the polishing pad; a base configured to support the arm so that the arm is spaced apart from the polishing pad; a manifold on a lower surface of the arm; and an anti-adsorption layer configured to at least partially cover a lower surface of the manifold, wherein the anti-adsorption layer is configured to prevent a chemical mechanical polishing slurry or other contaminants existing on the platen from being adsorbed on the manifold.

### CROSS-REFERENCE TO RELATED APPLICATION

This application is based on and claims priority under 35 U.S.C. § 119 to Korean Patent Application No. 10-2024-0062753, filed on May 13, 2024, in the Korean Intellectual Property Office, the disclosure of which is incorporated by reference herein in its entirety.

### BACKGROUND

### 1. Field

The disclosure relates to a chemical mechanical polishing apparatus, and more particularly, to a chemical mechanical polishing apparatus including an anti-adsorption layer.

### 2. Description of Related Art

With the development of electronics technology, the demand for high integration of semiconductor devices is increasing and the downscaling is in progress. As the degree of integration of semiconductor devices (or integrated circuit devices) increases, multi-layer wiring structures have been used to connect functional elements, such as transistors, capacitors, and resistors, to each other. In order to form the multi-layer wiring structures, a chemical mechanical polishing process is essentially required to planarize a non-metal-containing layer, such as an insulating material layer and a semiconductor material layer.

However, the chemical mechanical polishing process may cause scratches on a substrate. Also, these scratches may cause wiring bridge defects or residue sticking defects in semiconductor devices. That is, the scratches may deteriorate the reliability and electrical characteristics of the semiconductor devices. Therefore, it is important to control the scratches during the chemical mechanical polishing process.

### SUMMARY

Provided is a chemical mechanical polishing apparatus for preventing scratch defects during a chemical mechanical polishing process. Provide is a semiconductor device with improved reliability and electrical properties using the chemical mechanical polishing apparatus.

According to an aspect of the disclosure, a chemical mechanical polishing apparatus includes: a polishing pad on a platen; an arm extending from an edge of the polishing pad to a center of the polishing pad or at least near the center of the polishing pad; a base configured to support the arm so that the arm is spaced apart from the polishing pad; a manifold on a lower surface of the arm; and an anti-adsorption layer configured to at least partially cover a lower surface of the manifold, wherein the anti-adsorption layer is configured to prevent a chemical mechanical polishing slurry or other contaminants existing on the platen from being adsorbed on the manifold.

According to an aspect of the disclosure, a chemical mechanical polishing apparatus includes: a polishing pad on a platen; an arm extending from an edge of the polishing pad to a center of the polishing pad or at least near the center of the polishing pad; a base configured to support the arm so that the arm is spaced apart from the polishing pad; a manifold on a lower surface of the arm; a first anti-adsorption layer configured to at least partially cover a lower surface of the manifold; and a second anti-adsorption layer configured to at least partially cover a lowermost surface of the arm, wherein the first anti-adsorption layer and the second anti-adsorption layer are configured to prevent a chemical mechanical polishing slurry or other contaminants existing on the platen from being adsorbed on the manifold.

According to an aspect of the disclosure, a chemical mechanical polishing apparatus includes: a polishing pad on a platen; an arm extending from an edge of the polishing pad to a center of the polishing pad or at least near the center of the polishing pad; a base configured to support the arm so that the arm is spaced apart from the polishing pad; a manifold on a lower surface of the arm; an anti-adsorption layer configured to at least partially cover a lower surface of the manifold; a first inner pipe, a second inner pipe, and a third inner pipe, which are arranged inside the arm and spaced apart from each other; a polishing liquid supply system located outside the arm and connected to the first inner pipe; a heating system located outside the arm and connected to the second inner pipe; a cooling system located outside the arm and connected to the third inner pipe; and a carrier head disposed above the platen, spaced apart from the arm, and configured to support a substrate so that the substrate is brought into contact with the polishing pad, wherein the anti-adsorption layer comprises a hydrophobic material, and wherein the anti-adsorption layer is configured to prevent a chemical mechanical polishing slurry or other contaminants existing on the platen from being adsorbed on the manifold.

### BRIEF DESCRIPTION OF DRAWINGS

Embodiments will be more clearly understood from the following detailed description taken in conjunction with the accompanying drawings in which:

FIG. 1 is a cross-sectional view showing an example of a chemical mechanical polishing apparatus according to embodiments;

FIG. 2 is a cross-sectional view showing an example of a chemical mechanical polishing apparatus according to embodiments;

FIG. 3 is a top view showing an example of the chemical mechanical polishing apparatus of FIG. 1;

FIG. 4 is a diagram showing scratches formed on a substrate when using a chemical mechanical polishing apparatus according to the related art;

FIG. 5 is a cross-sectional view showing an example of a chemical mechanical polishing apparatus according to embodiments;

FIG. 6A is a cross-sectional view showing an example of a chemical mechanical polishing apparatus according to embodiments;

FIG. 6B is a plan view showing an arm of the chemical mechanical polishing apparatus of FIG. 6A;

FIG. 7 is a cross-sectional view showing an example of a chemical mechanical polishing apparatus according to embodiments;

FIG. 8 is a cross-sectional view showing an example of a chemical mechanical polishing apparatus according to embodiments; and

FIG. 9 is a plan view showing an arm of the chemical mechanical polishing apparatus of FIGS. 7 and 8.

### DETAILED DESCRIPTION OF EMBODIMENTS

Hereinafter, an embodiment is described in detail with reference to the accompanying drawings.

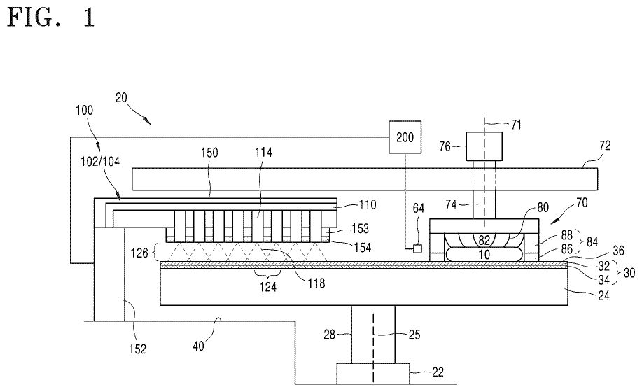

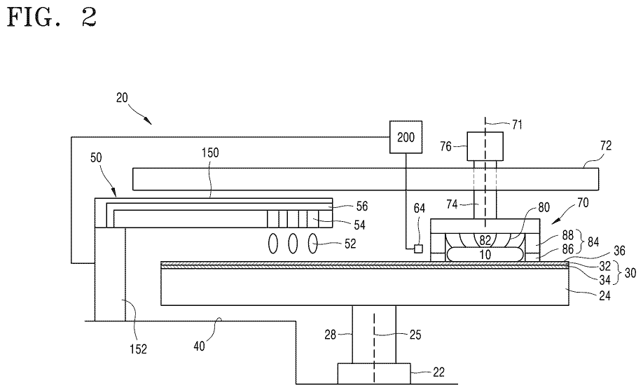

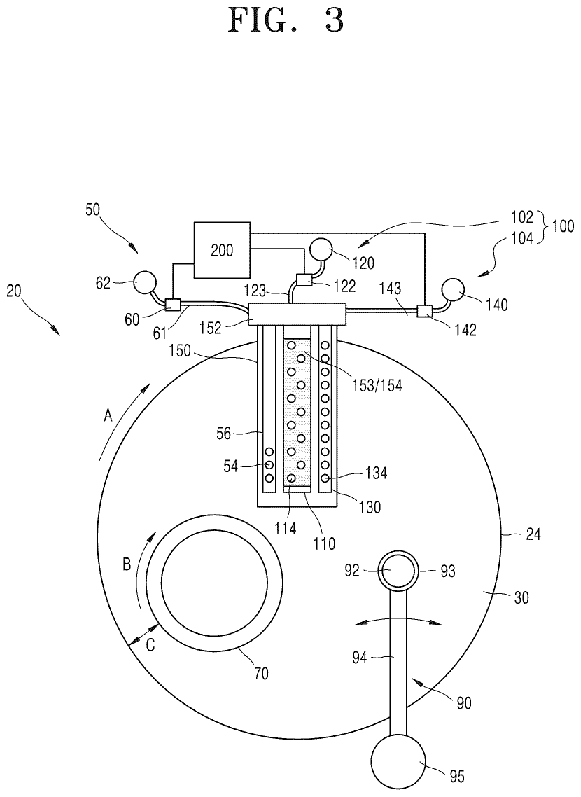

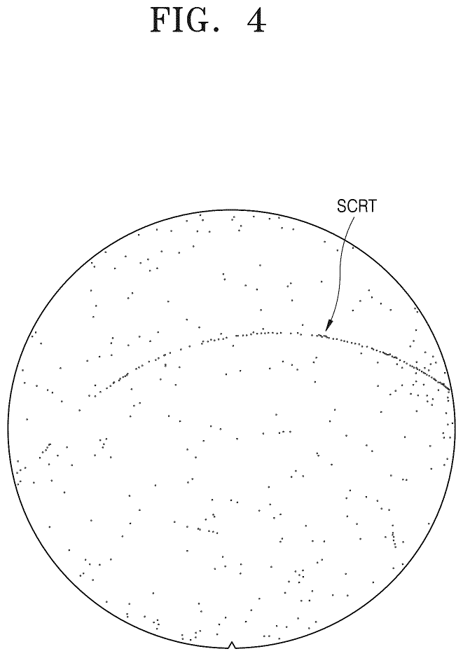

FIG. 1 is a cross-sectional view showing an example of a chemical mechanical polishing apparatus 20 according to embodiments. FIG. 2 is a cross-sectional view showing an example of a chemical mechanical polishing apparatus 20 according to embodiments. FIG. 3 is a top view showing an example of the chemical mechanical polishing apparatus 20 of FIG. 1. FIG. 4 is a diagram showing scratches formed on a substrate when using a chemical mechanical polishing apparatus according to the related art.

Referring to FIGS. 1 to 3, the chemical mechanical polishing apparatus 20 may include a rotatable disk-shaped platen 24 on which a polishing pad 30 is disposed. The chemical mechanical polishing apparatus 20 may also be referred to as a polishing station. The platen 24 may rotate around a first central axis 25. The platen 24 may rotate around the first central axis 25 as indicated by an arrow A in FIG. 3. A motor 22 may rotate a drive shaft 28 to rotate the platen 24.

In some embodiments, the polishing pad 30 may include a dual polishing pad having a lower polishing pad 34 and an upper polishing pad 32. The upper polishing pad 32 may include a softer material than the lower polishing pad 34.

The chemical mechanical polishing apparatus 20 may include a polishing liquid supply system 50 and a temperature control system 100.

The polishing liquid supply system 50 may include a first supply unit 62, a first control valve 60, and a first outer pipe 61. The first supply unit 62 may include a reservoir or tank that stores chemical mechanical polishing slurry 52 (or polishing liquid). The first control valve 60 may control the amount of chemical mechanical polishing slurry 52 that is supplied from the first supply unit 62 to the polishing pad 30 via a plurality of first openings 54. The first outer pipe 61 may include a passage through which the chemical mechanical polishing slurry 52 moves from the first supply unit 62 to an arm 150.

The chemical mechanical polishing slurry 52 may include a slurry liquid and abrasive particles. The slurry liquid may include an oxidizing agent, a hydroxylating agent, a surfactant, a dispersant, and other catalysts.

The dispersant may ensure the dispersion stability of ceria molecules. The dispersant may include nonionic polymers or cationic organic compounds.

For example, the dispersant may include at least one selected from a group consisting of ethylene oxide, ethylene glycol, glycol distearate, glycol monostearate, glycol polymerate, glycol ethers, alcohols containing alkylamine, polymerate ether, a compound containing sorbitol, nonionic surfactants, vinyl pyrrolidone, celluloses, and an ethoxylate-based compound.

Specifically, the dispersant may include at least one selected from a group consisting of diethylene glycol hexadecyl ether, decaethylene glycol hexadecyl ether, diethylene glycol octadecyl ether, eicosaethylene glycol octadecyl ether, diethylene glycol oley ether, decaethylene glycol oleyl ether, decaethylene glycol octadecyl ether, nonylphenol polyethylene glycol ether, ethylenediamine tetrakis(ethoxylate-block-propoxylate) tetrol, ethylenediamine tetrakis(propoxylate-block-ethoxylate) tetrol, polyethylene-block-poly(ethylene glycol), polyoxyethylene isooctylphenyl ether, polyoxyethylene octylphenyl ether, polyoxyethylene tridecyl ether, polyoxyethylene sorbitan tetraoleate, polyoxyethylene sorbitol hexaoleate, polyethylene glycol sorbitan monolaurate, polyoxyethylenesorbitan monolaurate, sorbitan monopalmitate, FS-300 nonionic fluorosurfactant, FSN nonionic fluorosurfactant, FSO nonionic ethoxylated fluorosurfactant, Vinyl pyrrolidone, celluloses, 2,4,7,9-tetramethyl-5-decyne-4,7-diol ethoxylate, 8-methyl-1-nonanol propoxylate-block-ethoxylate, allyl alcohol 1,2-butoxylate-block-ethoxylate, polyoxyethylene branched nonylcyclohexyl ether, and polyoxyethylene isooctylcyclohexyl ether. However, the disclosure may not be limited thereto.

A polish accelerating agent may include an aromatic-based amphipathic compound. The polish accelerating agent may include quinone compounds, such as 3-hydroxy-4-methyl-phenol anion, 3-hydroxy-4-hydroxymethyl-phenol anion, 4-methyl-benzene-1,3-diol, kojic acid, maltol propionate, and maltol iosbutyrate.

The quinone compound may include at least one selected from a group consisting of dienone, diol, and dienol(dienol anion), including alkylbenzene diols, a hydroxyl group, and an alkyl group, dienone, diol, and dienol anion, in which a phenol anion and an alkyl group are connected to each other by OXO, and dienone, diol, and dienol anion, including hydroxylalkyl and a benzene ring. However, the disclosure may not be limited thereto.

The abrasive particles may include silica, alumina, or ceria particles.

The temperature control system 100 may control the temperature of the polishing pad 30 and/or the chemical mechanical polishing slurry 52 on the polishing pad 30. The temperature control system 100 may deliver temperature-controlled fluids (e.g., a heating fluid 118 and a cooling fluid) onto a polishing surface 36 of the polishing pad 30. The temperature control system 100 may deliver the temperature-controlled fluid onto the chemical mechanical polishing slurry 52 already present on the polishing pad 30. The temperature control system 100 may include a heating system 102 and a cooling system 104.

The heating system 102 may include a second supply unit 120, a second control valve 122, and a second outer pipe 123. The second supply unit 120 may include a reservoir or tank that stores the heating fluid 118. In some embodiments, the second supply unit 120 may include a steam generator, for example, a vessel in which water is boiled to produce a steam gas. The second control valve 122 may control the amount of heating fluid 118 that is supplied from the second supply unit 120 to the polishing pad 30 via a plurality of second openings 114. The second outer pipe 123 may include a passage through which the heating fluid 118 moves from the second supply unit 120 to the arm 150.

The heating fluid 118 may be mixed with other gases (e.g., air) and/or liquids (e.g., heated water). Also, the heating fluid 118 may include substantially pure steam. If steam is used as the heating fluid 118, the temperature of the steam may be about 90° C. to about 200° C. when the steam is generated in the second supply unit 120. When the steam is distributed via the plurality of second openings 114, the temperature of the steam may be about 90° C. to about 150° C., for example, due to heat loss during transport. In some embodiments, the steam may be delivered via the plurality of second openings 114 at a temperature of about 60° C. to about 100° C., for example, about 60° C. to about 75° C.

The cooling system 104 may include a third supply unit 140, a third control valve 142, and a third outer pipe 143. The third supply unit 140 may include a reservoir or tank that stores the cooling fluid. The third control valve 142 may control the amount of cooling fluid that is supplied from the third supply unit 140 to the polishing pad 30 via one of a plurality of third openings 134. The third outer pipe 143 may include a passage through which the cooling fluid moves from the third supply unit 140 to the arm 150.

For example, the cooling fluid may be supplied onto the polishing pad 30 in the form of sprays. The cooling fluid may include a liquid, for example, water at a temperature below 20° C., a gas at a temperature below 20° C., or a mixture of liquid and gas. For example, the cooling fluid may include air with aerosolized water droplets. For example, the cooling fluid may include a mixture of nitrogen gas and de-ionized water (DIW).

The arm 150 may be disposed above the platen 24. The arm 150 may extend from an edge of the polishing pad 30 to the center of the polishing pad 30 or to at least near the center of the polishing pad 30. The arm 150 may be supported by a base 152. The base 152 may be supported on a frame 40 like the platen 24.

In some embodiments, the base 152 may include one or more actuators, such as a linear actuator for raising or lowering the arm 150 and a rotational actuator for swinging the arm 150 laterally above the platen 24. The arm 150 may be positioned so as not to collide with other hardware components, such as a carrier head 70 and a pad conditioning disk 92.

The plurality of first openings 54 may be arranged in the lowermost surface of the arm 150. The plurality of first openings 54 may be configured to guide the chemical mechanical polishing slurry 52 onto the polishing pad 30. FIG. 2 illustrates that the plurality of first openings 54 extends in the vertical direction so that the plurality of first openings 54 are connected to the first inner pipe 56 inside the arm 150. However, the plurality of first openings 54 are located only in the lowermost surface of the arm 150, and the first inner pipe 56 may further extend in the vertical direction so that the first inner pipe 56 is connected to the plurality of first openings 54.

A plurality of second openings 114 may be arranged in the lowermost surface of a manifold 153 and the lowermost surface of an anti-adsorption layer 154. FIG. 1 illustrates that the plurality of second openings 114 extend in the vertical direction so that the plurality of second openings 114 are connected to a second inner pipe 110 inside the arm 150. However, the plurality of second openings 114 are located only in the lowermost surface of the manifold 153 and the lowermost surface of the anti-adsorption layer 154, and the second inner pipe 110 may further extend in the vertical direction so that the second inner pipe 110 is connected to the plurality of second openings 114.

The plurality of second openings 114 may be configured to guide the heating fluid 118, such as a gas or vapor (or steam), onto the polishing pad 30. In some embodiments, the heating fluid 118 may be discharged in the form of sprays via the plurality of second openings 114. In some embodiments, the plurality of second openings 114 may be connected to a nozzle that guides the heating fluid 118 discharged in the form of sprays onto the polishing pad 30.

The plurality of second openings 114 may guide the heating fluid 118 in a radial pattern 124 on the polishing pad 30. FIG. 1 illustrates that the second openings 114 are spaced apart from each other by regular intervals, but the embodiment is not necessarily limited thereto. The second openings 114 may be arranged more densely toward the center of the polishing pad 30. FIG. 1 illustrates eight second openings 114, but more or fewer second openings 114 may be provided.

In some embodiments, a plurality of third openings 134 may be arranged in the lowermost surface of the arm 150. The plurality of third openings 134 may be configured to guide the cooling fluid onto the polishing pad 30. The diagram illustrates that the plurality of third openings 134 extend in the vertical direction so that the plurality of third openings 134 are connected to a third inner pipe 130 inside the arm 150. However, the plurality of third openings 134 are located only in the lowermost surface of the arm 150, and the third inner pipe 130 may further extend in the vertical direction so that the third inner pipe 130 is connected to the plurality of third openings 134.

The first inner pipe 56, the second inner pipe 110, and the third inner pipe 130 may be arranged inside the arm 150. The first inner pipe 56, the second inner pipe 110, and the third inner pipe 130 may be spaced apart from each other. The chemical mechanical polishing slurry 52 moving through the first inner pipe 56, the heating fluid 118 moving through the second inner pipe 110, and the cooling fluid moving through the third inner pipe 130 may not be mixed with each other. That is, the first inner pipe 56, the second inner pipe 110, and the third inner pipe 130 may be configured so as not to be connected to each other.

The first inner pipe 56, the second inner pipe 110, and the third inner pipe 130 may extend further into the base 152. The first inner pipe 56 extends further into the base 152 and may be connected to the polishing liquid supply system 50. The second inner pipe 110 extends further into the base 152 and may be connected to the heating system 102. The third inner pipe 130 extends further into the base 152 and may be connected to the cooling system 104.

In some embodiments, the first inner pipe 56, the second inner pipe 110, and the third inner pipe 130 may not extend into the base 152. In this case, the first outer pipe 61 of the polishing liquid supply system 50 may extend into the arm 150 and be connected to the first inner pipe 56. The second outer pipe 123 of the heating system 102 may extend into the arm 150 and be connected to the second inner pipe 110. The third outer pipe 143 of the cooling system 104 may extend into the arm 150 and be connected to the third inner pipe 130. This may vary depending on the design of the chemical mechanical polishing apparatus 20 to be manufactured.

The manifold 153 may be disposed on the lower surface of the arm 150. The manifold 153 may discharge the heating fluid 118, which has moved from the second inner pipe 110, onto the polishing pad 30 via the plurality of second openings 114. The heating fluid 118, which has been supplied via the second inner pipe 110, may be supplied onto the polishing pad 30 via the manifold 153.

The anti-adsorption layer 154 may be disposed on the manifold 153 so as to at least partially cover the lower surface thereof. The anti-adsorption layer 154 may partially cover the lower surface of the manifold 153 or may completely cover the lower surface of the manifold 153. The anti-adsorption layer 154 may not cover the plurality of second openings 114.

The anti-adsorption layer 154 may include a hydrophobic material. The anti-adsorption layer 154 may include a water-repellent coated layer. In some embodiments, the anti-adsorption layer 154 may correspond to a water-repellent coated layer.

For example, the anti-adsorption layer 154 may include silicon oxide (SiO₂), silicone resin, or a combination thereof. In another example, the anti-adsorption layer 154 may include a fluorocarbon material. The fluorocarbon material may include, for example, polytetrafluoroethylene (Teflon), polypropylene, or a combination thereof, but the disclosure is not limited thereto.

The silicon oxide, silicone resin, and fluorocarbon may not have hydrogen bonds, which represent electrostatic bonds between hydrogen and oxygen in atomic or molecular structures thereof. Accordingly, when the anti-adsorption layer 154 includes the silicon oxide, silicone resin, or fluorocarbon, the anti-adsorption layer 154 may exhibit hydrophobic characteristics. In particular, the fluorocarbon may have impervious characteristics to various substances, such as oil and oily substances.

The anti-adsorption layer 154 may have various thicknesses. The thickness of the anti-adsorption layer 154 may be in a range from several micrometers (μm) to hundreds of micrometers (μm). In some embodiments, the thickness of the anti-adsorption layer 154 may be in a range from several nanometers (nm) to hundreds of nanometers (nm). For example, the thickness of the anti-adsorption layer 154 may be in a range from about 1 nm to about 999 nm, about 10 nm to about 800 nm, about 20 nm to about 700 nm, and about 100 nm to about 600 nm. Preferably, the thickness of the anti-adsorption layer 154 may be in a range from about 10 nm to about 600 nm. However, this is only one example, and the thickness of the anti-adsorption layer 154 may vary depending on the design of the chemical mechanical polishing apparatus 20.

The anti-adsorption layer 154 may prevent the chemical mechanical polishing slurry 52 or other contaminants existing on the platen 24 from being adsorbed on the manifold 153. Specifically, the anti-adsorption layer 154 may include a hydrophobic material, and thus, the anti-adsorption layer 154 may prevent the chemical mechanical polishing slurry 52 containing water or other contaminants from being adsorbed on the manifold 153.

The polishing liquid supply system 50 and the temperature control system 100 may be connected to the arm 150 through the base 152. The polishing liquid supply system 50, the heating system 102, and the cooling system 104 may be connected to the arm 150 through the base 152.

The arm 150 may be connected to the first supply unit 62 through the first control valve 60 and the first outer pipe 61. The arm 150 may be connected to the second supply unit 120 through the second control valve 122 and the second outer pipe 123. The arm 150 may be connected to the third supply unit 140 through the third control valve 142 and the third outer pipe 143.

The first inner pipe 56, the second inner pipe 110, and the third inner pipe 130 may each extend from the inside of the arm 150 to the base 152.

The first inner pipe 56 may be connected to the polishing liquid supply system 50. The first inner pipe 56 may be connected to the first supply unit 62 through the first control valve 60 and the first outer pipe 61. The first inner pipe 56 may include a passage through which the chemical mechanical polishing slurry 52 supplied from the first supply unit 62 moves. The chemical mechanical polishing slurry 52 may be supplied onto the polishing pad 30 via the plurality of first openings 54 connected to the first inner pipe 56.

The second inner pipe 110 may be connected to the heating system 102. The second inner pipe 110 may be connected to the second supply unit 120 through the second control valve 122 and the second outer pipe 123. The second inner pipe 110 may include a passage through which the heating fluid 118 supplied from the second supply unit 120 moves. The heating fluid 118 may be supplied onto the polishing pad 30 through the manifold 153 via the second inner pipe 110 and the plurality of second openings 114.

Referring to FIG. 4, if the chemical mechanical polishing apparatus 20 does not include the anti-adsorption layer 154, scratches SCRT generated on a substrate 10 may be seen during a chemical mechanical polishing process.

If the anti-adsorption layer 154 is not present, the chemical mechanical polishing slurry 52 is splashed and adsorbed onto the arm 150 and the manifold 153 during the chemical mechanical polishing process. Then, the chemical mechanical polishing slurry 52 may be solidified and fixed thereto. In this case, when the heating fluid 118 is supplied through the manifold 153, the solidified and fixed chemical mechanical polishing slurry 52 may melt. The melted chemical mechanical polishing slurry 52 may cause scratches SCRT on the substrate 10.

These scratches SCRT may cause wiring bridge defects or residue sticking defects in semiconductor devices. That is, the scratches SCRT may deteriorate the reliability and electrical characteristics of the semiconductor devices. Therefore, the scratches SCRT may be an important factor to be controlled during the chemical mechanical polishing process.

Referring to FIGS. 1 to 4 together, the chemical mechanical polishing apparatus 20 according to the disclosure may include the anti-adsorption layer 154 that at least partially covers the lower surface of the manifold 153. The anti-adsorption layer 154 may prevent the chemical mechanical polishing slurry 52 or other contaminants existing on the platen 24 from being adsorbed on the manifold 153. Therefore, the scratches SCRT described above may not occur. Also, a semiconductor device manufactured by the chemical mechanical polishing process using the chemical mechanical polishing apparatus 20 may have improved electrical properties.

Referring back to FIGS. 1 to 3, the third inner pipe 130 may be connected to the cooling system 104. The third inner pipe 130 may be connected to the third supply unit 140 through the third control valve 142 and the third outer pipe 143. The third inner pipe 130 may be a passage through which the cooling fluid supplied from the third supply unit 140 moves. The cooling fluid may be supplied onto the polishing pad 30 through the plurality of third openings 134 connected to the third inner pipe 130.

The carrier head 70 may be disposed above the platen 24. The carrier head 70 may support the substrate 10 so that the substrate 10 is brought into contact with the polishing pad 30. The carrier head 70 may be referred to as a polishing head. The carrier head 70 may be connected to a support structure 72. The carrier head 70 may be connected to a rotary motor 76 by a drive shaft 74 and may rotate about a second central axis 71.

The carrier head 70 may include a flexible membrane 80 having a substrate mounting surface for establishing contact with the back surface (or the rear surface) of the substrate 10 and a pressurization chamber 82 for applying pressure on the substrate 10. The carrier head 70 may include a retaining ring 84 for supporting the substrate 10. The retaining ring 84 may include a lower retaining ring 86 and an upper retaining ring 88.

During operation of the chemical mechanical polishing apparatus 20, the platen 24 may rotate about the first central axis 25. Also, the carrier head 70 may rotate about the second central axis 71 as indicated by arrow B in FIG. 3 and may also move laterally across the uppermost surface of the polishing pad 30 as indicated by arrow C in FIG. 3.

The chemical mechanical polishing apparatus 20 may include a pad conditioner 90 having a conditioner disk 92 held by a conditioner head 93 at an end of a conditioner arm 94. The conditioner disk 92 may be used to maintain the surface roughness of the polishing pad 30. The conditioner arm 94 may be supported by a conditioner base 95.

In order to maintain a uniform surface condition of the polishing pad 30, the pad conditioner 90 may perform a conditioning process of polishing the surface of the polishing pad 30 with the conditioner disk 92, to which abrasive grains such as a plurality of diamond particles are attached, and reproducing the roughness of the polishing pad 30. The diameter of the abrasive particles in the chemical mechanical polishing slurry 52 may be in a range from about 50 micrometers to about 100 micrometers, and the greatest width of a diamond particle may be in a range from about 200 micrometers to about 250 micrometers. However, the disclosure may not be limited thereto.

The chemical mechanical polishing apparatus 20 may include a temperature sensor 64 for monitoring the temperature of the chemical mechanical polishing slurry 52 on the polishing pad 30 and/or the temperature of the polishing pad 30. For example, the temperature sensor 64 may include an infrared (IR) sensor, for example, an IR camera, which is positioned above the polishing pad 30 and configured to measure the temperature of the polishing pad 30 and/or the chemical mechanical polishing slurry 52 on the polishing pad 30.

The temperature sensor 64 may be configured to measure temperature at a plurality of points along the radius of polishing pad 30 so as to create a radial temperature profile. For example, the IR camera constituting the temperature sensor 64 may have a field of view spanning the radius of the polishing pad 30.

In some embodiments, the temperature sensor 64 may include a contact sensor rather than a non-contact sensor as in FIGS. 1 and 2. For example, the temperature sensor 64 may include a thermocouple or an IR thermometer located on the platen 24 or in the platen 24. The temperature sensor 64 may be in direct contact with the polishing pad 30. In some embodiments, in order to provide temperatures at a plurality of points along the radius of the polishing pad 30, a plurality of temperature sensors 64 may be spaced apart from each other at radial positions of the polishing pad 30.

FIGS. 1 and 2 illustrate that the temperature sensor 64 monitors the temperature of the polishing pad 30 and/or the chemical mechanical polishing slurry 52 on the polishing pad 30, but the temperature sensor 64 may be located inside the carrier head 70 to measure the temperature of the substrate 10. The temperature sensor 64 may include a contact sensor that is in direct contact with the substrate 10, that is, a semiconductor wafer.

The arm 150 may be supported by the base 152 so that the arm 150 is spaced apart from the polishing pad 30. A separation distance 126 between the plurality of second openings 114 and the polishing pad 30 may be about 0.5 mm to about 5 mm. In particular, the separation distance 126 may be selected such that heat of the heating fluid 118 is not significantly dissipated before the heating fluid 118 arrives at the polishing pad 30. For example, the separation distance 126 may be selected such that the heating fluid 118 discharged from the plurality of second openings 114 does not condense before arriving at the polishing pad 30.

The chemical mechanical polishing apparatus 20 may include a controller 200 for controlling the operation of the temperature control system 100. The controller 200 may be configured to receive temperature measurements from the temperature sensor 64. The controller 200 may compare the measured temperature with the target temperature and control the second control valve 122 and the third control valve 142 so that the flow rate of the heating fluid and/or cooling fluid onto the polishing pad 30 is adjusted to achieve the target temperature.

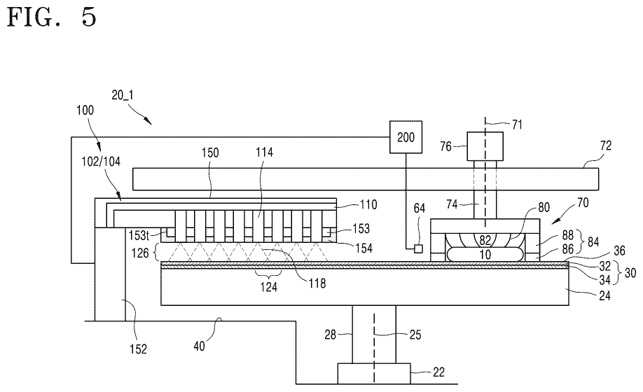

FIG. 5 is a cross-sectional view showing an example of a chemical mechanical polishing apparatus 20_1 according to embodiments. Hereinafter, repeated descriptions as those given with reference to FIGS. 1 to 3 are omitted, and only the differences therebetween are described.

Referring to FIG. 5, the anti-adsorption layer 154 of the chemical mechanical polishing apparatus 20_1 may further extend onto a sidewall 153t of the manifold 153. The anti-adsorption layer 154 may at least partially cover the sidewall 153t of the manifold 153. In some embodiments, the anti-adsorption layer 154 may completely cover the sidewall 153t of the manifold 153.

Referring to FIGS. 2, 4, and 5, if the anti-adsorption layer 154 does not at least partially cover the sidewall 153t of the manifold 153, the chemical mechanical polishing slurry 52 is splashed and adsorbed onto the sidewall 153t of the manifold 153 during the chemical mechanical polishing process. Then, the chemical mechanical polishing slurry 52 may be solidified and fixed thereto. In this case, when the heating fluid 118 is supplied through the manifold 153, the chemical mechanical polishing slurry 52 solidified and fixed to the sidewall 153t of the manifold 153 may be melted by heat. The melted chemical mechanical polishing slurry 52 may cause scratches SCRT on the substrate 10.

In some embodiments, the anti-adsorption layer 154 of the chemical mechanical polishing apparatus 20_1 according to the disclosure may at least partially cover the sidewall 153t of the manifold 153. In this case, it is possible to prevent the chemical mechanical polishing slurry 52 or other contaminants existing on the platen 24 from being adsorbed on the sidewall 153t of the manifold 153. Accordingly, scratches SCRT may not occur on the substrate 10. Also, a semiconductor device manufactured by the chemical mechanical polishing process using the chemical mechanical polishing apparatus 20_1 may have improved electrical properties.

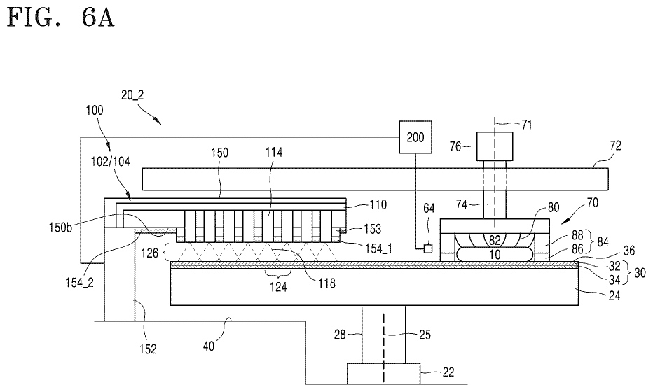

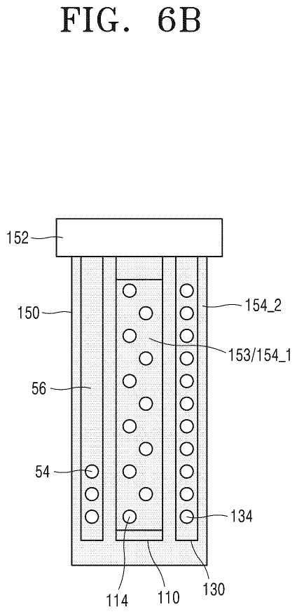

FIG. 6A is a cross-sectional view showing an example of a chemical mechanical polishing apparatus 20_2 according to embodiments. FIG. 6B is a plan view showing an arm 150 of the chemical mechanical polishing apparatus 20_2 of FIG. 6A. Hereinafter, repeated descriptions as those given with reference to FIGS. 1 to 3 are omitted, and only the differences therebetween are described.

Referring to FIGS. 6A and 6B, the chemical mechanical polishing apparatus 20_2 may include a first anti-adsorption layer 154_1 and a second anti-adsorption layer 154_2. The description of the first anti-adsorption layer 154_1 may be the same as the description of the anti-adsorption layer 154 described with reference to FIGS. 1 to 3.

The second anti-adsorption layer 154_2 may at least partially cover a lowermost surface 150b of the arm 150. For example, the second anti-adsorption layer 154_2 may completely cover the lowermost surface 150b of the arm 150. However, the second anti-adsorption layer 154_2 may not cover the lower surfaces of the plurality of first openings 54 and the plurality of third openings 134.

The plurality of first openings 54 and the plurality of third openings 134 may be located in the lower surface of the second anti-adsorption layer 154_2.

Referring to FIGS. 2, 4, 6A, and 6B, if the second anti-adsorption layer 154_2 at least partially covering the lowermost surface 150b of the arm 150 does not exist, the chemical mechanical polishing slurry 52 is splashed and adsorbed onto the lowermost surface 150b of the arm 150 during the chemical mechanical polishing process. Then, the chemical mechanical polishing slurry 52 may be solidified and fixed thereto. In this case, when the heating fluid 118 is supplied through the manifold 153, the chemical mechanical polishing slurry 52 solidified and fixed to the lowermost surface 150b of the arm 150 may be melted by heat that is transferred from the heating fluid 118. The melted chemical mechanical polishing slurry 52 may cause scratches SCRT on the substrate 10.

In some embodiments, the second anti-adsorption layer 154_2 of the chemical mechanical polishing apparatus 20_2 according to the disclosure may at least partially cover the lowermost surface 150b of the arm 150. In this case, it is possible to prevent the chemical mechanical polishing slurry 52 or other contaminants existing on the platen 24 from being adsorbed on the lowermost surface 150b of the arm 150. Accordingly, scratches SCRT may not occur on the substrate 10. Also, a semiconductor device manufactured by the chemical mechanical polishing process using the chemical mechanical polishing apparatus 20_2 may have improved electrical properties.

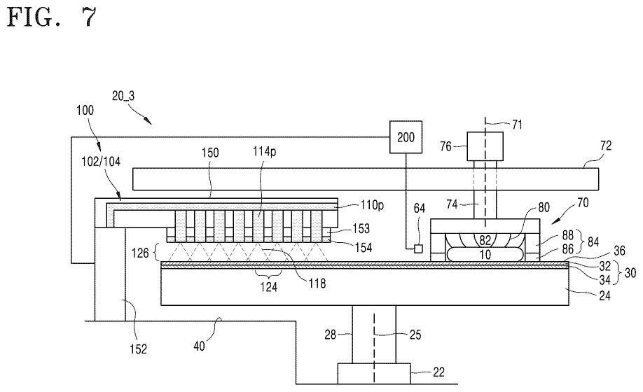

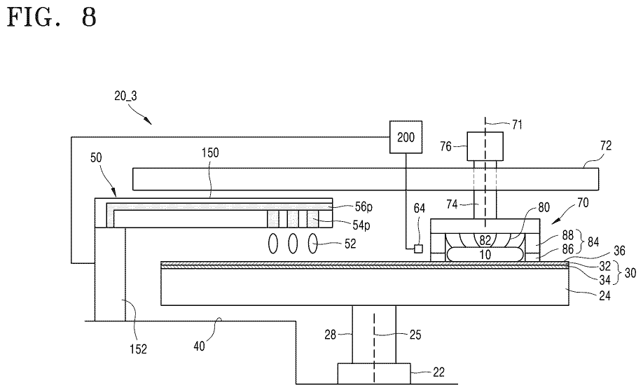

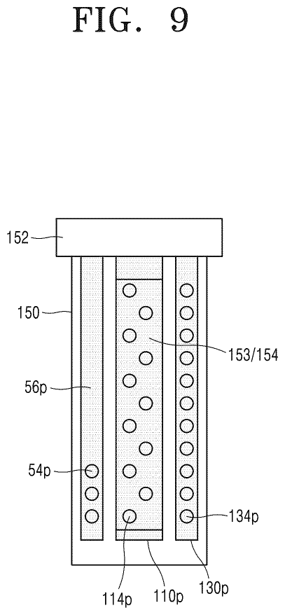

FIG. 7 is a cross-sectional view showing an example of a chemical mechanical polishing apparatus 20_3 according to embodiments. FIG. 8 is a cross-sectional view showing an example of the chemical mechanical polishing apparatus 20_3 according to embodiments. FIG. 9 is a plan view showing an arm 150 of the chemical mechanical polishing apparatus 20_3 of FIGS. 7 and 8.

Hereinafter, repeated descriptions as those given with reference to FIGS. 1 to 3 are omitted, and only the differences therebetween are described.

Referring to FIGS. 7, 8, and 9, a first inner pipe 56p, a second inner pipe 110p, and a third inner pipe 130p of the chemical mechanical polishing apparatus 20_3 may have water-repellent coated inner surfaces. That is, each of the inner surface of the first inner pipe 56p, the inner surface of the second inner pipe 110p, and the inner surface of the third inner pipe 130p may be at least partially covered by a water-repellent coated layer. The water-repellent coated layer may include materials of the anti-adsorption layer 154 described with reference to FIGS. 1 to 3.

Similarly, a plurality of first openings 54p, a plurality of second openings 114p, and a plurality of third openings 134p may have a water-repellent coated inner surface. That is, each of the inner surface of the plurality of first openings 54p, the inner surface of the plurality of second openings 114p, and the inner surface of the plurality of third openings 134p may be at least partially covered by a water-repellent coated layer. As described above, the water-repellent coated layer may include materials of the anti-adsorption layer 154 described with reference to FIGS. 1 to 3.

The inner surface of each of the first inner pipe 56p, the second inner pipe 110p, the third inner pipe 130p, the plurality of first openings 54p, the plurality of second openings 114p, and the plurality of third openings 134p may include a surface in contact with a moving fluid.

Referring to FIGS. 2, 4, 7, 8, and 9, if the water-repellent coated layer does not exist on the inner surface of each of the first inner pipe 56p, the second inner pipe 110p, the third inner pipe 130p, the plurality of first openings 54p, the plurality of second openings 114p, and the plurality of third openings 134p, the chemical mechanical polishing slurry 52 is splashed and adsorbed onto the inner surfaces described above during the chemical mechanical polishing process. Then, the chemical mechanical polishing slurry 52 may be solidified and fixed thereto. In this case, when the heating fluid 118 is supplied through the manifold 153, the solidified and fixed chemical mechanical polishing slurry 52 may be melted by heat that is transferred from the heating fluid 118. The melted chemical mechanical polishing slurry 52 may cause scratches SCRT on the substrate 10.

In some embodiments, the inner surface of each of the first inner pipe 56p, the second inner pipe 110p, the third inner pipe 130p, the plurality of first openings 54p, the plurality of second openings 114p, and the plurality of third openings 134p may be at least partially covered by the water-repellent coated layer. In this case, it is possible to prevent the chemical mechanical polishing slurry 52 or other contaminants existing on the platen 24 from being adsorbed on the inner surfaces described above. Accordingly, scratches SCRT may not occur on the substrate 10. Also, a semiconductor device manufactured by the chemical mechanical polishing process using the chemical mechanical polishing apparatus 20_3 may have improved electrical properties.

While the disclosure has been particularly shown and described with reference to embodiments thereof, various changes in form and details may be made therein without departing from the spirit and scope of the following claims.

What is claimed is:

1. A chemical mechanical polishing apparatus comprising:
a polishing pad on a platen;
an arm extending from an edge of the polishing pad to a center of the polishing pad or at least near the center of the polishing pad;
a base configured to support the arm so that the arm is spaced apart from the polishing pad;
a manifold on a lower surface of the arm; and
an anti-adsorption layer configured to at least partially cover a lower surface of the manifold,
wherein the anti-adsorption layer is configured to prevent a chemical mechanical polishing slurry or other contaminants existing on the platen from being adsorbed on the manifold.

2. The chemical mechanical polishing apparatus of claim 1, wherein the anti-adsorption layer comprises a hydrophobic material.

3. The chemical mechanical polishing apparatus of claim 1, wherein the anti-adsorption layer comprises silicon oxide, silicone resin, or a combination of the silicon oxide and the silicone resin.

4. The chemical mechanical polishing apparatus of claim 1, wherein the anti-adsorption layer comprises fluorocarbon.

5. The chemical mechanical polishing apparatus of claim 4, wherein the anti-adsorption layer comprises polytetrafluoroethylene (Teflon), polypropylene, or a combination of the polytetrafluoroethylene (Teflon) and the polypropylene.

6. The chemical mechanical polishing apparatus of claim 1, wherein a thickness of the anti-adsorption layer is in a range from about 10 nm to about 600 nm.

7. The chemical mechanical polishing apparatus of claim 1, wherein the anti-adsorption layer extends onto a sidewall of the manifold, and
wherein the anti-adsorption layer further at least partially covers the sidewall of the manifold.

8. The chemical mechanical polishing apparatus of claim 1, further comprising:
a first inner pipe located inside the arm;
a first opening located in the lower surface of the manifold and a lower surface of the anti-adsorption layer, the first opening being connected to the first inner pipe; and
a heating system located outside the arm and connected to the first inner pipe.

9. The chemical mechanical polishing apparatus of claim 8, further comprising:
a second inner pipe located inside the arm;
a second opening located in the lower surface of the arm and connected to the second inner pipe; and
a cooling system located outside the arm and connected to the second inner pipe.

10. The chemical mechanical polishing apparatus of claim 8, wherein the anti-adsorption layer includes a water-repellent coated layer, and
wherein an inner surface of the first opening is at least partially covered by the water-repellent coated layer.

11. The chemical mechanical polishing apparatus of claim 10, wherein an inner surface of the first inner pipe is at least partially covered by the water-repellent coated layer.

12. A chemical mechanical polishing apparatus comprising:
a polishing pad on a platen;
an arm extending from an edge of the polishing pad to a center of the polishing pad or at least near the center of the polishing pad;
a base configured to support the arm so that the arm is spaced apart from the polishing pad;
a manifold on a lower surface of the arm;
a first anti-adsorption layer configured to at least partially cover a lower surface of the manifold; and
a second anti-adsorption layer configured to at least partially cover a lowermost surface of the arm,
wherein the first anti-adsorption layer and the second anti-adsorption layer are configured to prevent a chemical mechanical polishing slurry or other contaminants existing on the platen from being adsorbed on the manifold.

13. The chemical mechanical polishing apparatus of claim 12, wherein each of the first anti-adsorption layer and the second anti-adsorption layer comprises a hydrophobic material.

14. The chemical mechanical polishing apparatus of claim 12, wherein each of the first anti-adsorption layer and the second anti-adsorption layer comprises silicon oxide, silicone resin, fluorocarbon, a combination of the silicon oxide and the silicone resin, a combination of the silicon oxide and the fluorocarbon, a combination of the silicone resin and the fluorocarbon, or a combination of the silicon oxide, the silicone resin, and the fluorocarbon.

15. The chemical mechanical polishing apparatus of claim 14, wherein the fluorocarbon comprises polytetrafluoroethylene, polypropylene, or a combination of the polytetrafluoroethylene and the polypropylene.

16. The chemical mechanical polishing apparatus of claim 12, wherein the first anti-adsorption layer extends onto a sidewall of the manifold, and
wherein the first anti-adsorption layer further at least partially covers the sidewall of the manifold.

17. The chemical mechanical polishing apparatus of claim 12, wherein a thickness of each of the first anti-adsorption layer and the second anti-adsorption layer is in a range from about 10 nm to about 600 nm.

18. The chemical mechanical polishing apparatus of claim 12, further comprising:
a first inner pipe located inside the arm;
a first opening located in the lower surface of the manifold and a lower surface of the second anti-adsorption layer, the first opening being connected to the first inner pipe; and
a heating system located outside the arm and connected to the first inner pipe.

19. A chemical mechanical polishing apparatus comprising:
a polishing pad on a platen;
an arm extending from an edge of the polishing pad to a center of the polishing pad or at least near the center of the polishing pad;
a base configured to support the arm so that the arm is spaced apart from the polishing pad;
a manifold on a lower surface of the arm;
an anti-adsorption layer configured to at least partially cover a lower surface of the manifold;
a first inner pipe, a second inner pipe, and a third inner pipe, which are arranged inside the arm and spaced apart from each other;
a polishing liquid supply system located outside the arm and connected to the first inner pipe;
a heating system located outside the arm and connected to the second inner pipe;
a cooling system located outside the arm and connected to the third inner pipe; and
a carrier head disposed above the platen, spaced apart from the arm, and configured to support a substrate so that the substrate is brought into contact with the polishing pad,
wherein the anti-adsorption layer comprises a hydrophobic material, and
wherein the anti-adsorption layer is configured to prevent a chemical mechanical polishing slurry or other contaminants existing on the platen from being adsorbed on the manifold.

20. The chemical mechanical polishing apparatus of claim 19, further comprising an opening located in the lower surface of the manifold,
wherein the opening is connected to the second inner pipe.
